(19) United States
(12) Patent Application Publication
(10) Pub. No.: US 2025/0070035 A1
(43) Pub. Date: Feb. 27, 2025

(54) ELECTRONIC DEVICE

(71) Applicant: InnoLux Corporation, Miao-Li County (TW)

(72) Inventors: Chia-Chun LIU, Miao-Li County (TW); Hao-Jung HUANG, Miao-Li County (TW)

(21) Appl. No.: 18/780,899

(22) Filed: Jul. 23, 2024

Related U.S. Application Data
(60) Provisional application No. 63/520,954, filed on Aug. 22, 2023.

(30) Foreign Application Priority Data
May 28, 2024 (CN) 202410667826.7

(51) Int. Cl. H01L 23/538; H01L 23/00; H01L 23/31; H01L 25/075; H01L 25/16

(52) U.S. Cl. CPC H01L 23/5386; H01L 23/5383; H01L 25/167; H01L 23/3107; H01L 24/08; H01L 25/0753; H01L 2224/08225

(57) ABSTRACT

An electronic device is provided. The electronic device includes at least one electrical connection structure. The at least one electrical connection structure includes a first substrate, a first conductive pad, a second substrate, a second conductive pad, a through hole, and a conductive material. The first conductive pad is disposed on the first substrate. The first conductive pad includes a first upper surface. The second conductive pad is disposed on the second substrate. The second conductive pad includes a second upper surface. The through hole penetrates through the first substrate. In addition, in a top-view diagram, an area of the through hole is larger than an area of the first conductive pad. The conductive material is partially disposed in the through hole and in contact with the first upper surface and the second upper surface.

### CROSS REFERENCE TO RELATED APPLICATIONS

This application claims the benefit of China Application No. 202410667826.7, filed May 282024, which claims the benefit of provisional Application No. 63/520,954, filed Aug. 22, 2023, the entirety of which are incorporated by reference herein.

### BACKGROUND

### Technical Field

The present disclosure is related to an electronic device, and in particular it is related to an electrical connection structure of an electronic device.

### Description of the Related Art

Electronic devices such as tablet computers, notebook computers, smartphones, monitors, and televisions have become indispensable necessities in modern society. As the application of electronic devices and the habits or needs of users change, the requirements for the structure and quality of electronic devices are getting higher and higher, thereby causing electronic devices to face many different problems.

For example, in response to higher resolution or display quality requirements, the size of the electrical connection structure in the electronic device needs to be miniaturized accordingly, which can affect the reliability or conduction capability of the electrical connection structure.

As described above, existing electronic devices still do not meet the requirements in all respects. Further improving the performance of the electrical connection structure of electronic devices is still one of the current research topics in the industry.

### SUMMARY

In accordance with some embodiments of the present disclosure, an electronic device is provided. The electronic device includes at least one electrical connection structure. The at least one electrical connection structure includes a first substrate, a first conductive pad, a second substrate, a second conductive pad, a through hole and a conductive material. The first conductive pad is disposed on the first substrate. The first conductive pad includes a first upper surface. The second conductive pad is disposed on the second substrate. The second conductive pad includes a second upper surface. The through hole penetrates through the first substrate. In addition, in a top-view diagram, an area of the through hole is larger than an area of the first conductive pad. The conductive material is partially disposed in the through hole and in contact with the first upper surface and the second upper surface.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a top-view diagram of an electronic device in accordance with some embodiments of the present disclosure;

FIG. 2 is a cross-sectional diagram of the electronic device taken along the section line A-A′ in FIG. 1 in accordance with some embodiments of the present disclosure;

FIG. 3 is a cross-sectional diagram of an electrical connection structure of an electronic device in accordance with some embodiments of the present disclosure;

FIG. 4 is a top-view diagram of some components of an electrical connection structure of an electronic device in accordance with some embodiments of the present disclosure;

FIG. 5A and FIG. 5B are top-view diagrams of some components of an electrical connection structure of an electronic device in accordance with some embodiments of the present disclosure;

FIG. 6A and FIG. 6B are top-view diagrams of some components of an electrical connection structure of an electronic device in accordance with some embodiments of the present disclosure;

FIGS. 7A to 7E are top-view diagrams of some components of an electrical connection structure of an electronic device in accordance with some embodiments of the present disclosure;

FIG. 8 is a cross-sectional diagram of an electronic device in accordance with some embodiments of the present disclosure.

### DETAILED DESCRIPTION

The electronic device according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness, height, volume or area of each element, or spacing or distance between elements. Specifically, in accordance with some embodiments, a scanning electron microscope can be used to obtain a cross-sectional image including the elements to be measured, and measure the width, thickness, height, volume or area of each element, or spacing or distance between elements.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In response to higher resolution or display quality requirements, the size of the electrical connection structure in electronic devices needs to be miniaturized accordingly, and the reliability and conduction performance of the electrical connection structure are thus challenged.

In accordance with some embodiment of the present disclosure, an electronic device including an electrical connection structure is provided. The through hole and conductive pad of the electrical connection structure are configured in a specific manner, so that the conductive material can be effectively electrically connected to the conductive pad even in the miniaturized through hole. Moreover, it can reduce the contact resistance between the conductive material and the conductive pad, and has good conduction function, which can improve the reliability of the electrical connection structure and thereby improve the performance of the electronic device. The electronic device can have good electrical quality or display quality. In addition, in accordance with some embodiments of the present disclosure, the design of the electrical connection structure allows electronic components (such as driving components, etc.) to be disposed on the back side of the substrate, which can reduce the usage rate of the peripheral area of the electronic device, thereby achieving technical requirements such as borderless, narrow border or seamless tiling.

In accordance with some embodiments of the present disclosure, the electronic device may include a display device, a tiled device, a touch electronic device, a sensing device, an antenna device, a packaging device, a curved electronic device or a non-rectangular electronic device, but it is not limited thereto. The electronic device may include, for example, liquid crystal, light-emitting diode, fluorescence, phosphor, other suitable display media, or a combination thereof, but it is not limited thereto. The display device may be a non-self-luminous display device or a self-luminous display device. The electronic device may include electronic components, which may be passive components or active components, such as capacitors, resistors, inductors, diodes, driving components, transistors, etc. The diode may include a light-emitting diode (LED) or a photodiode. The light-emitting diode may include, for example, an organic light-emitting diode (OLED), a mini light-emitting diode (mini LED), a micro light-emitting diode (micro LED) or a quantum dot light-emitting diode (quantum dot LED), but it is not limited thereto. The tiled device may be, for example, a tiled display device, but it is not limited thereto. The antenna device may be, for example, a liquid-crystal antenna or a varactor diode antenna device, but it is not limited thereto. The packaging device may be used in wafer level packaging (WLP) technology or panel level packaging (WLP) technology, such as chip first or RDL first process. It should be noted that the electronic device can be any combination of the above, but it is not limited thereto. In addition, the electronic device may be a bendable or flexible electronic device. Moreover, the shape of the electronic device may be a rectangular shape, a circular shape, a polygonal shape, a shape with curved edges, or other suitable shapes. The electronic device may have a peripheral system such as a driving system, a control system, a light source system, a shelf system, etc. to support a display device or tiled device.

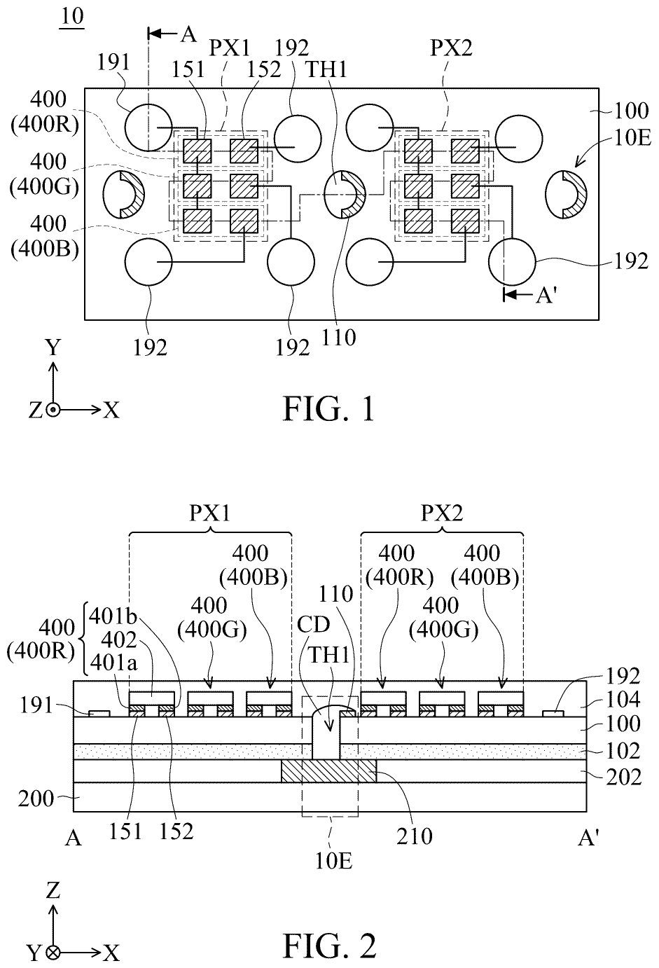

Please refer to FIG. 1 and FIG. 2. FIG. 1 is a top-view diagram of an electronic device 10 in accordance with some embodiments of the present disclosure. FIG. 2 is a cross-sectional diagram of the electronic device 10 taken along the section line A-A′ in FIG. 1 in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below. In accordance with some other embodiments, some features of the electronic device 10 described below may be replaced or omitted.

The electronic device 10 includes at least one electrical connection structure 10E. In the following description, the electronic device 10 is used as a display device and the electrical connection structure 10E is applied to the display device as an example, but the present disclosure is not limited thereto. It should be understood that the electrical connection structure 10E can also be applied to another suitable electronic device to provide electrical connection functions.

As shown in FIG. 1 and FIG. 2, in accordance with some embodiments, the electronic device 10 includes a first substrate 100, a second substrate 200, an electronic component 400, and an electrical connection structure 10E. The second substrate 200 may be disposed opposite to the first substrate 100. The electronic component 400 may be disposed on the first substrate 100, and the electronic component 400 may be electrically connected to another electronic component (not illustrated, such as a driving component, etc.) on the second substrate 200 through the electrical connection structure 10E. In accordance with some embodiments, the electronic component 400 includes a light-emitting diode, and the electronic device 10 can be, for example, a light-emitting diode display device. In this way, the electronic component 400 can be driven by another electronic component (not illustrated, which can be a driving component, etc.) disposed on the back side of the first substrate, which can reduce the usage rate of the usage rate of the peripheral area of the electronic device 10, thereby achieving technical requirements such as borderless, narrow border or seamless tiling. The electronic device 10 can therefore have good display quality.

In accordance with some embodiments, the first substrate 100 can be used as an active array substrate, and includes, for example, a base (not illustrated) and a circuit element layer (not illustrated) disposed on the base. The base of the first substrate 100 may include a rigid substrate, a flexible substrate, or a combination thereof. In accordance with some embodiments, the material of the base of the first substrate 100 may include glass, quartz, sapphire, polyimide (PI), polycarbonate (PC), polyethylene terephthalate (PET), polypropylene (PP), polydimethylsiloxane (PDMS), another suitable base material or a combination thereof, but it is not limited thereto. Furthermore, the circuit element layer may include, for example, a stack of at least one or more circuit elements (e.g., thin-film transistors), buffer layers, and insulating layers, but it is not limited thereto. In accordance with some embodiments, the circuit element layer is, for example, an active array layer composed of a plurality of thin-film transistors, but it is not limited thereto.

Please continue to refer to FIG. 1 and FIG. 2. In accordance with some embodiments, one or more electronic components 400 may form a pixel, and multiple pixels (for example, a pixel PX1 and a pixel PX2) may be disposed on the first substrate 100. As described above, the electronic component 400 may be a light-emitting diode. In other words, in accordance with some embodiments, each pixel may include multiple light-emitting diodes (for convenience of explanation, they are labeled as an electronic component 400R, an electronic component 400G and an electronic component 400B in FIG. 1), and the amount of light-emitting diodes is not limited. For example, the two pixels PX1 and PX2 shown in FIG. 1 may be arranged in an array by the X direction and Y direction directions in the figure (the X direction is perpendicular to the Y direction and Z direction, and the Y direction is perpendicular to the X direction and Z direction), but it is not limited thereto. It should be understood that the amount of pixels and the arrangement pattern shown in FIG. 1 are only examples. In fact, the amount of pixels may be tens, tens of thousands, or millions or more, but it is not limited thereto.

In accordance with some embodiments, the plurality of light-emitting diodes may include red light-emitting diodes, green light-emitting diodes, blue light-emitting diodes, white light-emitting diodes, yellow light-emitting diodes or light-emitting diodes of other colors, which can be adjusted according to design requirements. In accordance with some embodiments, the aforementioned electronic component 400R, electronic component 400G and electronic component 400B can serve as sub-pixels, and a combination of multiple pixels PX1 and pixels PX2 can be used to generate image patterns. In accordance with some embodiments, the amount of the light-emitting diodes in the pixel PX1 and the pixel PX2 may be three or more, and the colors of the light-emitting diodes may include red light, blue light, green light, white light, yellow light, light or another suitable color, but it is not limited thereto.

In accordance with some embodiments, the electronic component 400 may include an electrode 401a, an electrode 401b, and a body portion 402. The body portion 402 may include, for example, a first-type semiconductor layer (such as an N-type doped semiconductor layer), a second-type semiconductor layer (such as a P-type doped semiconductor layer), and a light-emitting layer located between the first-type semiconductor layer and the second-type semiconductor layer. That is, the body portion 402 may be a p-n junction light-emitting diode, but it is not limited thereto. Furthermore, although the electronic component 400 illustrated in the figure is a flip-chip LED, the present disclosure is not limited thereto. In accordance with some other embodiments, the electronic component 400 may also include a vertical LED, a face-up LED, or LED packaged by another suitable manner.

In accordance with some embodiments, the electronic component 400 may be electrically connected to the circuit element layer of the first substrate 100. Specifically, a plurality of first pads 151 and a plurality of second pads 152 may be disposed on the first substrate 100 or the circuit element layer. One of the plurality of light-emitting diodes may be disposed corresponding to the first contact pad 151 and the adjacent second contact pad 152. For example, the electrode 401a of the electronic component 400R may be electrically connected to the first contact pad 151, and the electrode 401b may be electrically connected to the second contact pad 152, but it is not limited thereto. In this way, the first contact pad 151 and the second contact pad 152 can respectively serve as pads connected to the positive electrode or the negative electrode of the electronic component 400. For example, the electronic component 400 may be electrically connected to the first contact pad 151 and the second contact pad 152 through wire bonding, flip chip die bonding, or eutectic die bonding. In addition, in accordance with some other embodiments, the electronic component 400 may also use a transfer layer including conductive lines and insulating layers, so that the electrode 401a and/or the electrode 401b can be electrically connected to the circuit elements (for example, thin-film transistors) or circuit layers in the circuit element layer through the conductive lines, but it is not limited thereto.

In accordance with some embodiments, the electronic device 10 may optionally include a first test pad 191 and a plurality of second test pads 192. The first test pad 191 and the second test pads 192 may be respectively disposed adjacent to one side of the pixel (for example, the pixel PX1), but it is not limited thereto. The first test pad 191 and the second test pads 192 may be electrically connected to the circuit element layer of the first substrate 100, but it is not limited thereto. The first test pad 191 may connect multiple first pads 151 in series. The second test pads 192 may be electrically connected to the second pads 152 respectively. In accordance with some embodiments, the first test pad 191 and the second test pads 192 can serve as test electrodes for detecting the electrical quality of the plurality of electronic components 400 in the pixel PX1 and the pixel PX2.

The materials of the first test pad 191, the second test pad 192, the first contact pad 151 and the second contact pad 152 may include conductive materials. In accordance with some embodiments, the first test pad 191, the second test pad 192, the first contact pad 151 and the second contact pad 152 may include a metal conductive material, such as molybdenum (Mo), titanium (Ti), Tantalum (Ta), niobium (Nb), hafnium (Hf), nickel (Ni), chromium (Cr), cobalt (Co), zirconium (Zr), Tungsten (W), aluminum (Al), copper (Cu), silver (Ag), gold (Au), alloys of the above materials, another suitable conductive material or a combination thereof, but it is not limited thereto. In accordance with some embodiments, the first test pad 191, the second test pad 192, the first contact pad 151 and the second contact pad 152 may include a transparent conductive material. The transparent conductive material may include, for example, a transparent conductive oxide (TCO), such as indium tin oxide (ITO), antimony zinc oxide (AZO), tin oxide (SnO), zinc oxide (ZnO), indium zinc oxide (indium zinc oxide, IZO), indium gallium zinc oxide (IGZO), indium tin zinc oxide (ITZO), antimony tin oxide (ATO), another suitable transparent conductive material, or a combination thereof, but it is not limited thereto.

As shown in FIG. 2, in accordance with some embodiments, the electronic device 10 may further include a cover layer 104 disposed on the first substrate 100. Furthermore, in accordance with some embodiments, the cover layer 104 may be disposed on the circuit element layer of the first substrate 100, the cover layer 104 may cover the first test pad 191 and the second test pad 192, and may at least partially cover electronic component 400. In accordance with some embodiments, the cover layer 104 may cover the plurality of electronic components 400 and the electrical connection structure 10E. In accordance with some embodiments, the cover layer 104 may cover the first test pad 191, the second test pad 192, the plurality of electronic components 400 and the electrical connection structure 10E, but it is not limited thereto. The cover layer 104 can provide at least one of the functions of electrical insulation, protection of the related components that are covered, flat surface, etc. The cover layer 104 may be formed by coating, spraying, dispensing, printing or another suitable method, but it is not limited thereto. In accordance with some embodiments, the cover layer 104 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), polyethylene, silicone, acrylic, polyurethane epoxy, another suitable material or a combination thereof, but it is not limited thereto.

In accordance with some embodiments, the second substrate 200 is disposed below the first substrate 100, and the second substrate 200 and the plurality of electronic components 400 are located on opposite surfaces of the first substrate 100. The second substrate 200 can serve as a circuit substrate. In accordance with some embodiments, the second substrate 200 may include a printed circuit board (PCB), a redistribution layer (RDL), or a combination thereof, but it is not limited thereto. In accordance with some other embodiments, the second substrate 200 may include a chip on film (COF), but it is not limited thereto.

Specifically, in accordance with some embodiments, the second substrate 200 may include a base and multiple insulating layers and interconnect layers (e.g., patterned conductive layers) disposed on the base. As shown in FIG. 2, in accordance with some embodiments, the electronic device 10 may further include an insulating layer 202 and a second conductive pad 210. The insulating layer 202 and the second conductive pad 210 may also be part of the insulating layer and interconnect layer of the second substrate 200. The insulating layer 202 and the second conductive pad 210 may be disposed between the second substrate 200 and the first substrate 100. In accordance with some other embodiments, the second substrate 200 may be an interposer.

The base of the second substrate 200 may include a rigid substrate, a flexible substrate, or a combination thereof. In accordance with some embodiments, the material of the base of the second substrate 200 may include glass, quartz, sapphire, polyimide (PI), polycarbonate (PC), polyethylene terephthalate (PET), polypropylene (PP), polydimethylsiloxane (PDMS), another suitable base material or a combination thereof, but it is not limited thereto.

In accordance with some embodiments, the insulating layer 202 may include a polymer insulating material, for example, may include Ajinomoto Build-up Film (ABF), polybenzoxazole (PBO), polyimide (PI), photosensitive polyimide (PSPI), benzocyclobutene (BCB), PrePreg, photoimageable dielectric (PID), resin coated cooper foil (RCC), flame-resistant fiberglass (FR4), fiberglass resin composite material, another suitable insulating material or a combination thereof, but it is not limited thereto.

In accordance with some embodiments, the electronic device 10 may further include an intermediate layer 102, and the intermediate layer 102 may be disposed between the first substrate 100 and the second substrate 200. In detail, a part of the intermediate layer 102 may be disposed between the insulating layer 202 and the first substrate 100, and a part of the intermediate layer 102 may be disposed between the second substrate 200 and the first substrate 100. In accordance with some embodiments, the intermediate layer 102 may be an adhesive layer that can combine the first substrate 100 and the second substrate 200. For example, the intermediate layer 102 may be disposed on the second substrate 200 and then be combined with the first substrate 100, or the intermediate layer 102 may be disposed on the first substrate 100 and then combined with the second substrate 200. In accordance with some embodiments, the material of the intermediate layer 102 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), polyethylene, another suitable material or a combination thereof, but it is not limited thereto. In addition, in accordance with some embodiments, the intermediate layer 102 may include an adhesive material, such as optical clear adhesive (OCA), optical clear resin (OCR), pressure sensitive adhesive (OCR), or optical clear resin (OCR), pressure sensitive adhesive (PSA), acrylic glue, acrylic resin, another suitable material, or a combination thereof, but it is not limited thereto. Furthermore, the intermediate layer 102 may have a single-layer or multi-layer structure.

In addition, the electronic device 10 includes at least one electrical connection structure 10E. The electrical connection structure 10E may be disposed between the electronic components 400, for example, between two adjacent pixels PX1 and PX2, but it is not limited thereto. In other words, in accordance with some embodiments, the electrical connection structure 10E may be disposed in the active area and/or peripheral area of the electronic device 10. The electrical connection structure 10E can be applied to any suitable electronic device to provide electrical connection functions. The detailed structure of the electrical connection structure 10E will be described below.

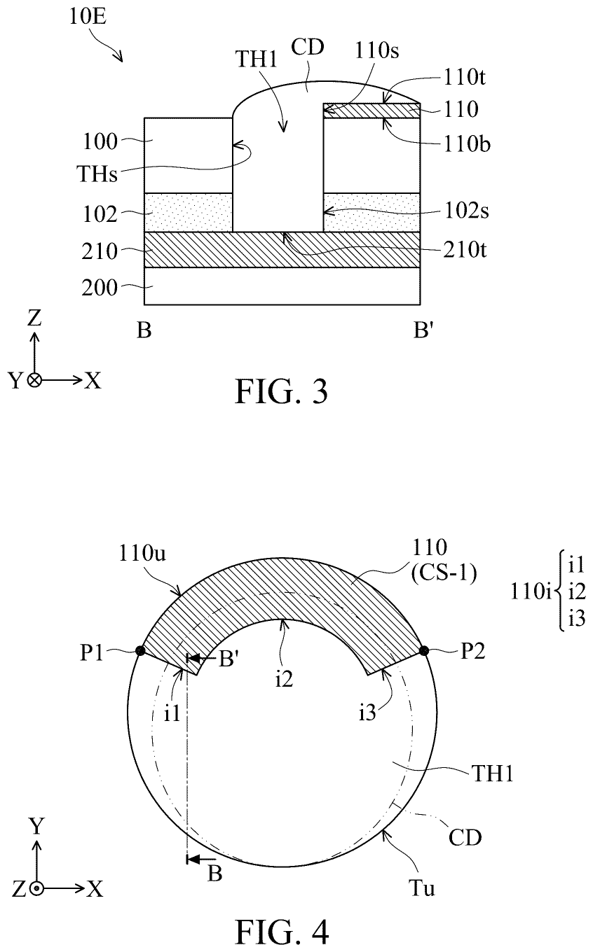

Please refer to FIG. 3 and FIG. 4. FIG. 3 is a cross-sectional diagram of an electrical connection structure 10E of an electronic device in accordance with some embodiments of the present disclosure. FIG. 4 is a top-view diagram of some components of the electrical connection structure 10E of an electronic device in accordance with some embodiments of the present disclosure. Specifically, FIG. 3 is a cross-sectional diagram of the electrical connection structure 10E taken along the section line B-B′ in FIG. 4. Furthermore, FIG. 4 only illustrates the first conductive pad 110, the through hole TH1 and the conductive material CD of the electrical connection structure 10E to clearly explain the positional relationship between them. Moreover, the top-view diagram shown in FIG. 4 substantially corresponds to a horizontal position of the lower surface 110b of the first conductive pad 110 in FIG. 3.

In addition, it should be understood that the components or elements that are the same or similar to those mentioned above will be represented by the same or similar numbers below, and their materials and functions are the same or similar as those mentioned above, and thus will not be repeated in the following description.

First, as shown in FIG. 3, the electrical connection structure 10E may include a first substrate 100, a first conductive pad 110, a second substrate 200, a second conductive pad 210, a through hole TH1 and a conductive material CD.

The first conductive pad 110 may be disposed on the first substrate 100. The first conductive pad 110 includes an upper surface 110t, a side surface 110s and a lower surface 110b. In accordance with some embodiments, the first conductive pad 110 may be disposed on the topmost insulating layer of the circuit element layer (not illustrated) of the first substrate 100. For example, the lower surface 110b of the first conductive pad 110 may be in contact with the topmost insulating layer of the circuit element layer, but it is not limited thereto. As shown in FIG. 4, in accordance with some embodiments, in a top-view diagram, the shape of the first conductive pad 110 is not a complete circle or annular shape, and the first conductive pad 110 may have an arc, curved or concave profile, but it is not limited thereto.

The first conductive pad 110 may include conductive material. In accordance with some embodiments, the first conductive pad 110 may include a metal conductive material, such as molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), silver (Ag), gold (Au), alloys of the foregoing materials, another suitable conductive material or a combination thereof, but it is not limited thereto. In accordance with some embodiments, the material of the first conductive pad 110 may include a transparent conductive material. The transparent conductive material may include, for example, transparent conductive oxide (TCO), but it is not limited thereto.

The second conductive pad 210 may be disposed on the second substrate 200. The second conductive pad 210 includes an upper surface 210t. In accordance with some embodiments, the second conductive pad 210 may be a part of the interconnect layer of the second substrate 200, but it is not limited thereto. In accordance with some embodiments, the second conductive pad 210 may be further electrically connected to an electronic component (not illustrated, which may be, for example, a driving component) disposed on the second substrate 200.

Furthermore, the material of the second conductive pad 210 may be the same or similar to the material of the first conductive pad 110, and thus will not be repeated\ here.

In accordance with some embodiments, the electrical connection structure 10E may further include an intermediate layer 102, which may be disposed between the first substrate 100 and the second substrate 200 and partially cover the second conductive pad 210.

The through hole TH1 may pass through the first substrate 100. In accordance with some embodiments, the through hole TH1 may pass through the first substrate 100 and the intermediate layer 102 and expose a portion of the upper surface 210t of the second conductive pad 210. As shown in FIG. 4, in a top-view diagram, the area of the through hole TH1 is greater than the area of the first conductive pad 110, and the conductive material CD is partially disposed in the through hole TH1 and is in contact with the upper surface 110t of the first conductive pad 110 and the upper surface 210t of the second conductive pad 210. The first conductive pad 110 may be electrically connected to the second conductive pad 210 through the through hole TH1. Specifically, the conductive material CD may pass through the through hole TH1, so that the first conductive pad 110 and the second conductive pad 210 may be electrically connected to each other. In accordance with some embodiments, the conductive material CD may be in contact with the upper surface 110t, the side surface 110s of the first conductive pad 110, and the upper surface 210t of the second conductive pad 210. In accordance with some embodiments, the conductive material CD may be in contact with the upper surface 110t, the side surfaces 110s of the first conductive pad 110, the first substrate 100, the intermediate layer 102, and the upper surface 210t of the second conductive pad 210.

As shown in FIG. 3, in accordance with some embodiments, the side surface THs of the through hole TH1 may be substantially perpendicular to the upper surface 210t of the second conductive pad 210. In accordance with some other embodiments, the side surface THs of the through hole TH1 may not be perpendicular to the upper surface 210t of the second conductive pad 210. That is, the side surface THs of the through hole TH1 may be inclined, for example, may be inclined inward (the top width of the through hole TH1 smaller than the bottom width), or may be inclined outward (the top width of the through hole TH1 is larger than the bottom width). In accordance with some other embodiments, the side surface THs of the through hole TH1 may have irregular profile, but it is not limited thereto.

Furthermore, the conductive material CD may be partially filled in the through hole TH1 or entirely filled in the through hole TH1. For example, in accordance with some other embodiments (not illustrated), during the process of filling the through hole TH1 with the conductive material CD, there may be a gap between the side surface of the conductive material CD in the through hole TH1 and the side surface THs of the through hole TH1. In accordance with some embodiments (not illustrated), a portion of the side surface of the conductive material CD may not in contact with the side surface THs of the through hole TH1 and/or the side surface 102s of the intermediate layer 102. During the process of disposing the conductive material CD in the through hole TH1, the air bubbles generated can be released through the gap between the side surface of the conductive material CD and the side surface THs of the through hole TH1. In this way, the risk of bubbles existing in the conductive material CD can be reduced, thereby reducing the problem of poor contact or abnormal electrical connection between the conductive material CD and the first conductive pad 110 or the second conductive pad 210.

In accordance with some embodiments, part of the first substrate 100 and the intermediate layer 102 may be removed through one or more photolithography processes and/or etching processes to form the through hole TH1. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

Furthermore, the conductive material CD may include a conductive material. In accordance with some embodiments, the conductive material CD may include silver paste, copper paste, conductive solder, another suitable conductive material, or a combination thereof, but it is not limited thereto. In accordance with some embodiments, the conductive material CD may be disposed in the through hole TH1 by using solder paste printing, micro inkjet printing (MJP) process, chemical vapor deposition (CVD) process, physical vapor deposition (PVD) process, an electroplating process, an electroless plating process, another suitable method or a combination thereof.

As described above, in the top-view diagram, the area of the through hole TH1 is greater than the area of the first conductive pad 110. In accordance with some embodiments, in the top-view diagram, the electrical connection structures 10E of the same size may be designed, or the electrical connection structures 10E of different sizes may be designed according to the user's needs. In response to the above user's needs, the ratio of the area of the through hole TH1 to the area of the first conductive pad 110 of the designed electrical connection structure 10E may be between 1.1:1 and 100:1, or between 1.5:1 and 75:1, or between 2:1 and 50:1. For example, the ratio of the area of the through hole TH1 to the area of the first conductive pad 110 may be 1.3:1, 1.75:1, 3.5:1, 4.5:1, 5.5:1, 6.5:1, 7.5:1, 8.5:1, 9.5:1, 10:1, 15:1, 20:1, 25:1, 30:1, 35:1, 40:1, 45:1, 50:1, 55:1, 60:1, 65:1, 70:1, 75:1, 80:1, 85:1, 90:1, or 95:1, but it is not limited thereto.

The area of the first conductive pad 110 refers to the area occupied by the first conductive pad 110 in a cross section corresponding to the horizontal position of the lower surface 110b of the first conductive pad 110 in FIG. 3. The area of the through hole TH1 mentioned above refers to the area occupied by the through hole TH1 in a cross section corresponding to the horizontal position of the lower surface 110b of the first conductive pad 110 in FIG. 3.

It should be noted that the area of the through hole TH1 is greater than the area of the first conductive pad 110, and the through hole TH1 has a relatively large area. Therefore, a relatively large amount of conductive material CD can be filled in, so that the contact area between conductive material CD and the second conductive pad 210 is greater than the contact area between the conductive material CD and the first conductive pad 110, thereby reducing the contact resistance between the conductive material CD and the first conductive pad 110 and the contact resistance between the conductive pad 110 and the second conductive pad 210. In particular, when the area of the through hole TH1 and the area of the first conductive pad 110 have the aforementioned proportional relationship, the conductive material CD can be electrically connected to the first conductive pad 110 and the second conductive pad 210 effectively even in the miniaturized through hole TH1. It provides good conduction function and can improve the reliability of the electrical connection structure.

As shown in FIG. 4, in accordance with some embodiments, in a top-view diagram, the first conductive pad 110 includes a continuous surface CS-1. Specifically, the first conductive pad 110 has an outer edge 110u and an inner edge 110i, and the outer edge 110u and the inner edge 110i form the continuous surface CS-1. The inner edge 110i of the first conductive pad 110 may have a single or multiple line segments. Specifically, in this embodiment, the inner edge 110i of the first conductive pad 110 has a line segment i1, a line segment i2, and a line segment i3, and the outer edge 110u of the first conductive pad 110 has a first endpoint P1 and a second endpoint P2. The line segment i1 is connected to the first endpoint P1 of the outer edge 110u, the line segment i2 is connected to the line segment i1 and the line segment i3, and the line segment i3 is connected to the second endpoint P2 of the outer edge 110u. In accordance with some embodiments, in a top-view diagram, the inner edge 110i (e.g., the line segment i2) of the first conductive pad 110 has at least an arc shape, the outer edge 110u of the first conductive pad 110 has at least an arc shape, and an outer edge Tu of the through hole TH1 and the outer edge 110u of the first conductive pad 110 are substantially continuous. In other words, the outer edge Tu of the through hole TH1 and the outer edge 110u of the first conductive pad 110 have substantially continuous contours. However, in the manufacturing process, such as the process of manufacturing the through hole TH1 and/or the first conductive pad 110, there may be a process tolerance value between the design value and the actual value. In accordance with some embodiments, in a top-view diagram, the outer edge Tu of the through hole TH1 and the outer edge 110u of the first conductive pad 110 may be at least partially overlapped or slightly misaligned (not illustrated). There may be a minimum distance between the outermost edge of the through hole TH1 and the outermost edge of the first conductive pad 110, and the minimum distance may be between 0.01 and 100 micrometers (um), or between 0.01 and 50 micrometers, or between 0.01 and 30 micrometers, but it is not limited thereto. In accordance with some embodiments, the first endpoint P1 and the second endpoint P2 may overlap with the outer edge Tu of the through hole TH1. Specifically, in the normal direction of the first substrate 100 (for example, the Z direction in the figure), the first endpoint P1 may overlap with the outer edge Tu of the through hole TH1, and the second endpoint P2 may also overlap with the outer edge Tu of the through hole TH1. However, in the manufacturing process, such as the process of manufacturing the through hole TH1 and/or the first conductive pad 110, there may be a process tolerance value between the design value and the actual value. In accordance with some embodiments, in a top-view diagram, the first endpoint P1 and the outer edge Tu of the through hole TH1 may be at least partially overlapped or slightly misaligned (not illustrated). There may be a minimum distance between the center point of the first endpoint P1 and the outermost edge of the through hole TH1, and the minimum distance may be between 0.01 and 100 micrometers, or between 0.01 and 50 micrometers, or between 0.01 and 30 micrometers, but it is not limited thereto. In accordance with some embodiments, in a top-view diagram, the second endpoint P2 may also overlap with the outer edge Tu of the through hole TH1, and the first endpoint P1 and the outer edge Tu of the through hole TH1 may be at least partially overlapped or slightly misaligned (not illustrated). There may be a distance between the center point of the second endpoint P2 and the outermost edge of the through hole TH1, and the distance may be between 0.01 and 100 micrometers, or between 0.01 and 50 micrometers, or between 0.01 and 30 micrometers, but it is not limited thereto.

In accordance with some embodiments, the outer edge Tu of the through hole TH1 and the outer edge 110u of the first conductive pad 110 may be combined to form a circle or a quasi-circle. In a top-view diagram, the outer edge Tu and the outer edge 110u may form a circular or circular-like contour. In accordance with some embodiments, the curvature of the outer edge Tu of the through hole TH1 may be substantially the same as the curvature of the outer edge 110u of the first conductive pad 110. In accordance with some embodiments, the curvature of the outer edge Tu of the through hole TH1 may be substantially the same as that of the inner edge 110i (e.g., the line segment i2) of the first conductive pad 110, but is not limited thereto.

In particular, when the outer edge Tu of the through hole TH1 and the outer edge 110u of the first conductive pad 110 are combined to form a circle or a quasi-circle, the electrical connection structure can be effectively miniaturized and occupy a relatively small space in the electronic device. In addition, the conductive material CD can still be well connected with the first conductive pad 110 and the second conductive pad 210, thereby maintaining the reliability of the electrical connection structure.

Furthermore, the outer edge Tu of the aforementioned through hole TH1 and the outer edge 110u of the first conductive pad 110 may be combined to form a quasi-circle. This means that the shape formed by connecting the outer edge Tu and the outer edge 110u in the top-view diagram is not completely circular, but is similar to a circle.

As described above, the inner edge 110i of the first conductive pad 110 may have a single or multiple line segments, and the inner edge 110i of the first conductive pad 110 may have any suitable shape. The slopes or curvatures of multiple line segments may be partly the same and partly different. In this embodiment, the inner edge 110i may have a plurality of line segments, the line segments i1 and i3 may be straight lines, and the line segment i2 may be an arc, but the present disclosure is not limited thereto.

In addition, it should be understood that the components or elements that are the same or similar to those mentioned above will be represented by the same or similar numbers below, and their materials and functions are the same or similar as those mentioned above, and thus will not be repeated in the following description.

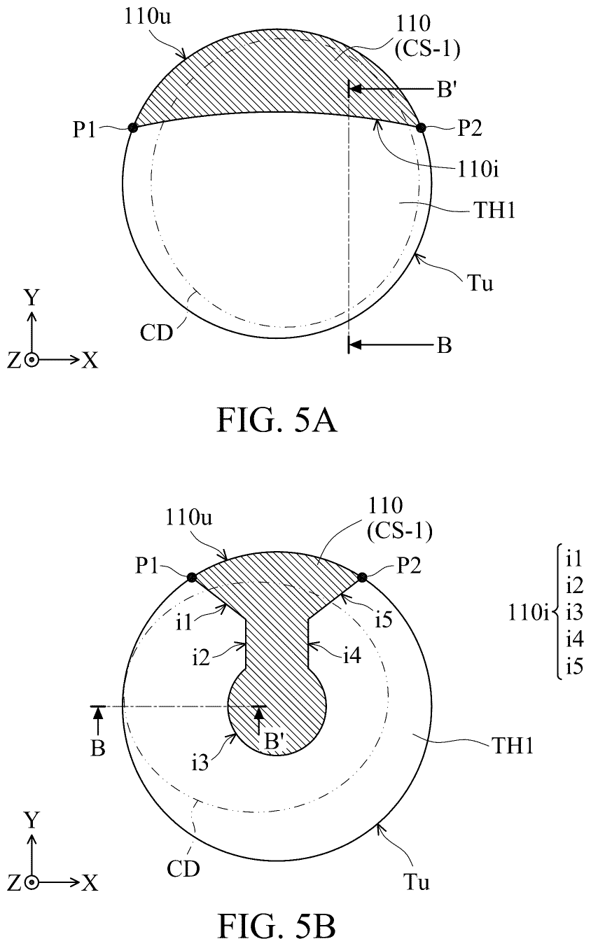

Next, please refer to FIG. 5A and FIG. 5B, which are top-view diagrams of some components of an electrical connection structure of an electronic device in accordance with some embodiments of the present disclosure. Similarly, FIG. 5A and FIG. 5B only illustrate the first conductive pad 110, the through hole TH1 and the conductive material CD of the electrical connection structure to clearly explain the positional relationship between them. Moreover, the top-view diagrams shown in FIG. 5A and FIG. 5B substantially correspond to a horizontal position of the lower surface 110b of the first conductive pad 110 in FIG. 3.

Please refer to FIG. 5A. In this embodiment, in the top-view diagram, the area of the through hole TH1 is also greater than the area of the first conductive pad 110, and the ratio of the area of the through hole TH1 to the area of the first conductive pad 110 may be between 1.1:1 and 100:1. Furthermore, the first conductive pad 110 includes a continuous surface CS-1. The inner edge 110i of the first conductive pad 110 has a single line segment, and the inner edge 110i is connected to the first endpoint P1 and the second endpoint P2 of the outer edge 110u. In the top-view diagram, the inner edge 110i of the first conductive pad 110 has at least an arc shape, the outer edge 110u of the first conductive pad 110 has at least an arc shape, and the outer edge Tu of the through hole TH1 and the outer edge 110u of the first conductive pad 110 are continuous. Furthermore, the first endpoint P1 and the second endpoint P2 overlap with the outer edge Tu of the through hole TH1.

In this embodiment, the outer edge Tu of the through hole TH1 and the outer edge 110u of the first conductive pad 110 may be combined to form a circle or a quasi-circle. In this embodiment, the curvature of the outer edge Tu of the through hole TH1 is substantially the same as the curvature of the outer edge 110u of the first conductive pad 110, and the curvature of the outer edge Tu of the through hole TH1 is different from the curvature of the inner edge 110i of the first conductive pad 110.

Please refer to FIG. 5B. In this embodiment, in the top-view diagram, the area of the through hole TH1 is also greater than the area of the first conductive pad 110, and the ratio of the area of the through hole TH1 to the area of the first conductive pad 110 may be between 1.1:1 and 100:1. Furthermore, the first conductive pad 110 includes a continuous surface CS-1. In this embodiment, the inner edge 110i of the first conductive pad 110 has a plurality of line segments. Specifically, the inner edge 110i of the first conductive pad 110 has a line segment i1, a line segment i2, a line segment i3, a line segment i4 and a line segment i5. The outer edge 110u of a conductive pad 110 has a first endpoint P1 and a second endpoint P2. The line segment i1 is connected to the first endpoint P1 of the outer edge 110u. The line segment i2 is connected to the line segment i1 and the line segment i3. The line segment i3 is connected to the line segment i2 and the line segment i4. The line segment i4 is connected to line segment i3 and line segment i5. The line segment i5 is connected to the second endpoint P2 of the outer edge 110u. In the top-view diagram, the inner edge 110i (e.g., the line segment i3) of the first conductive pad 110 has at least an arc shape, the outer edge 110u of the first conductive pad 110 has at least an arc shape, and the outer edge Tu of the through hole TH1 and the outer edge 110u of the first conductive pad 110 are continuous. Furthermore, the first endpoint P1 and the second endpoint P2 overlap with the outer edge Tu of the through hole TH1.

In this embodiment, the outer edge Tu of the through hole TH1 and the outer edge 110u of the first conductive pad 110 may be combined to form a circle or a quasi-circle. In this embodiment, the curvature of the outer edge Tu of the through hole TH1 is substantially the same as the curvature of the outer edge 110u of the first conductive pad 110, and the curvature of the outer edge Tu of the through hole TH1 is different from the inner edge 110i of the first conductive pad 110. As described above, the inner edge 110i of the first conductive pad 110 may have a plurality of line segments, the line segments i1, i2, i4, and i5 may be straight lines, and the line segment i3 may be an arc. In other words, the first conductive pad 110 may have arc angle, but the present disclosure is not limited thereto. In addition, in this embodiment, the first conductive pad 110 may extend toward the interior of the through hole TH1 and overlap with the geometric center of the through hole TH1. Specifically, in the normal direction of the first substrate 100 (for example, the Z direction in the figure), the first conductive pad 110 may overlap with the geometric center of the through hole TH1. For example, the through hole TH1 may surround a portion of the inner edge 110i of the first conductive pad 110.

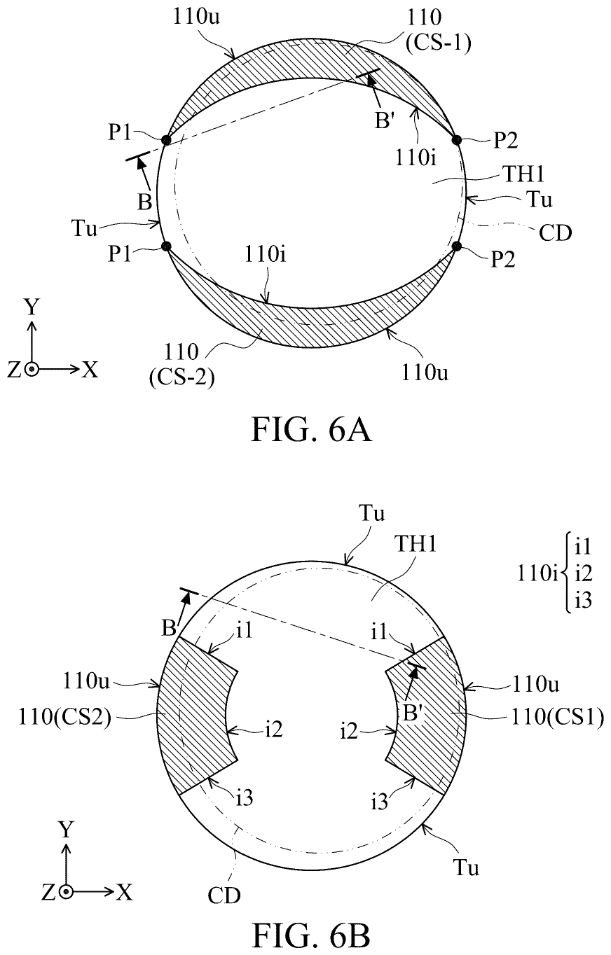

Next, please refer to FIG. 6A and FIG. 6B, which are top-view diagrams of some components of an electrical connection structure of an electronic device in accordance with some embodiments of the present disclosure. Similarly, FIG. 6A and FIG. 6B only illustrate the first conductive pad 110, the through hole TH1 and the conductive material CD of the electrical connection structure to clearly explain the positional relationship between them. Moreover, the top-view diagrams shown in FIG. 6A and FIG. 6B substantially correspond to a horizontal position of the lower surface 110b of the first conductive pad 110 in FIG. 3.

Please refer to FIG. 6A. In this embodiment, in the top-view diagram, the area of the through hole TH1 is also greater than the area of the first conductive pad 110 (the total area, such as the total area of the continuous surface CS-1 and the continuous surface CS-2), and the ratio of the area of the through hole TH1 to the area of the first conductive pad 110 may be between 1.1:1 and 100:1. Furthermore, in the top-view diagram, the first conductive pad 110 includes two continuous surfaces, a continuous surface CS-1 and a continuous surface CS-2, but it is not limited thereto. In accordance with some embodiments, the first conductive pad 110 may include at least two continuous surfaces, that is, may include two or more continuous surfaces. The continuous surface CS-1 and the continuous surface CS-2 may have the same or different shapes. Furthermore, as shown in FIG. 6A, the continuous surface CS-1 and the continuous surface CS-2 may be arranged oppositely, or symmetrically arranged on both sides of the geometric center of the through hole TH1, but it is not limited thereto. In accordance with some embodiments, in the top-view diagram, the conductive material CD overlaps with at least one continuous surface of the first conductive pad 110.

In this embodiment, the inner edge 110i of the first conductive pad 110 has a single line segment, and the inner edge 110i is connected to the first endpoint P1 and the second endpoint P2 of the outer edge 110u. In the top-view diagram, the inner edge 110i of the first conductive pad 110 has at least an arc shape, the outer edge 110u of the first conductive pad 110 has at least an arc shape, and the outer edge Tu of the through hole TH1 and the outer edge 110u of the first conductive pad 110 are continuous. Furthermore, the first endpoint P1 and the second endpoint P2 overlap with the outer edge Tu of the through hole TH1.

In this embodiment, the outer edge Tu of the through hole TH1 and the outer edge 110u of the first conductive pad 110 may be combined to form a circle or a quasi-circle. In this embodiment, the curvature of the outer edge Tu of the through hole TH1 is substantially the same as the curvature of the outer edge 110u of the first conductive pad 110, and the curvature of the outer edge Tu of the through hole TH1 is different from the inner edge 110i of the first conductive pad 110.

Please refer to FIG. 6B. In this embodiment, in the top-view diagram, the area of the through hole TH1 is also greater than the area of the first conductive pad 110 (the total area of the continuous surface CS-1 and the continuous surface CS-2), and the ratio of the area of the through hole TH1 to the area of the first conductive pad 110 may be between 1.1:1 and 100:1. Furthermore, in the top-view diagram, the first conductive pad 110 includes two continuous surfaces, a continuous surface CS-1 and a continuous surface CS-2, but it is not limited thereto. The continuous surface CS-1 and the continuous surface CS-2 may have the same or different shapes. As shown in FIG. 6B, the continuous surface CS-1 and the continuous surface CS-2 may be arranged oppositely, or symmetrically arranged on both sides of the geometric center of the through hole TH1, but it is not limited thereto.

In this embodiment, the inner edge 110i of the first conductive pad 110 has a plurality of line segments. Specifically, the inner edge 110i of the first conductive pad 110 has a line segment i1, a line segment i2 and a line segment i3, and the outer edge 110u of the first conductive pad 110 has a first endpoint P1 and a second endpoint P2. The line segment i1 is connected to the first endpoint P1 of the outer edge 110u. The line segment i2 is connected to the line segment i1 and the line segment i3. The line segment i3 is connected to the second endpoint P2 of the outer edge 110u. In the top-view diagram, the inner edge 110i (e.g., the line segment i2) of the first conductive pad 110 has at least an arc shape, the outer edge 110u of the first conductive pad 110 has at least an arc shape, and the outer edge Tu of the through hole TH1 and the outer edge 110u of the conductive pad 110 are continuous. Furthermore, the first endpoint P1 and the second endpoint P2 overlap with the outer edge Tu of the through hole TH1.

In this embodiment, the outer edge Tu of the through hole TH1 and the outer edge 110u of the first conductive pad 110 may be combined to form a circle or a quasi-circle. In this embodiment, the curvature of the outer edge Tu of the through hole TH1 is substantially the same as the curvature of the outer edge 110u of the first conductive pad 110, and the curvature of the outer edge Tu of the through hole TH1 is substantially the same as the curvature of the inner edge 110i of the first conductive pad 110 (e.g., the line segment i2). As described above, the inner edge 110i of the first conductive pad 110 may have a plurality of line segments, the line segments i1 and i3 may be straight lines, and the line segment i2 may be an arc, but the present disclosure is not limited thereto.

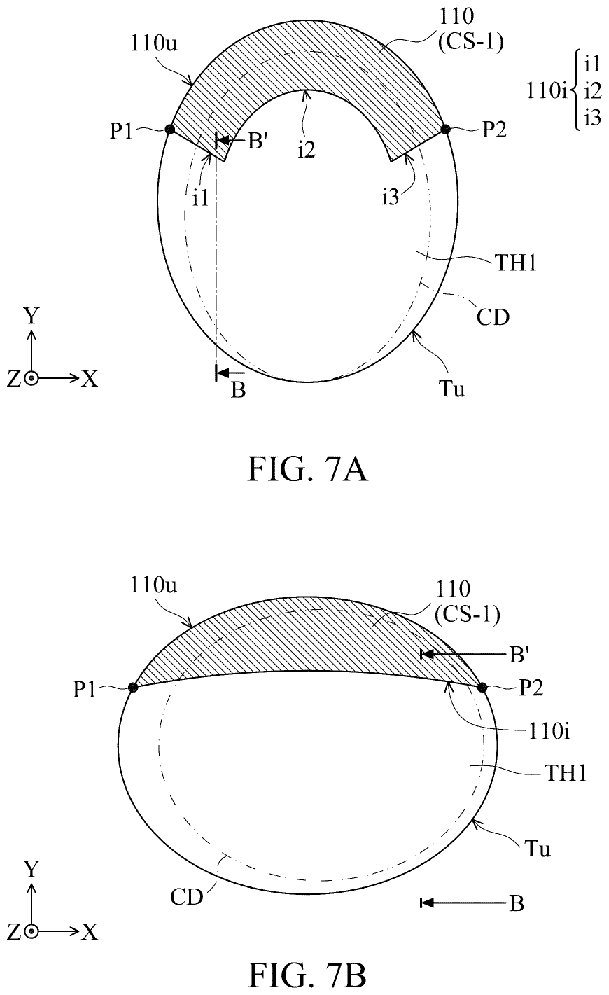

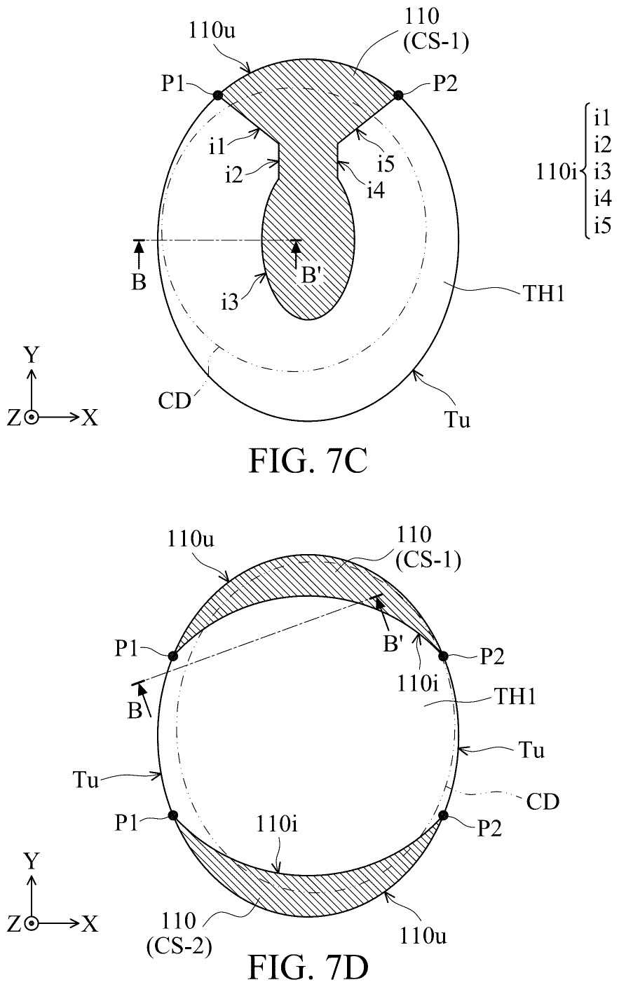

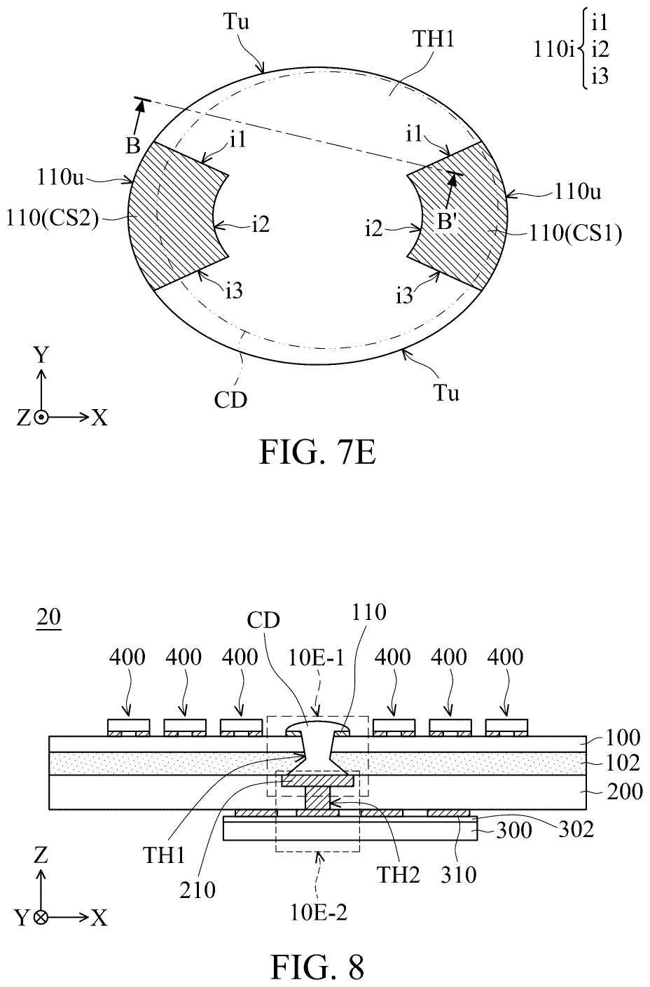

Next, please refer to FIGS. 7A to 7E, which are top-view diagrams of some components of an electrical connection structure of an electronic device in accordance with some embodiments of the present disclosure. Similarly, FIGS. 7A to 7E only illustrate the first conductive pad 110, the through hole TH1 and the conductive material CD of the electrical connection structure to clearly explain the positional relationship between them. Moreover, the top-view diagrams shown in FIGS. 7A to 7E substantially correspond to a horizontal position of the lower surface 110b of the first conductive pad 110 in FIG. 3.

FIGS. 7A to 7E are substantially similar to the embodiments of FIG. 4A, FIG. 5A, FIG. 5B, FIG. 6A and FIG. 6B respectively. However, in the embodiments of FIGS. 7A to 7E, the outer edge Tu of the through hole TH1 and the outer edge 110u of the first conductive pad 110 are combined to form an ellipse. That is, the outer edge Tu of the through hole TH1 and the outer edge 110u of the first conductive pad 110 may form an elliptical contour. In these embodiments, the curvature of the outer edge Tu of the through hole TH1 and the curvature of the outer edge 110u of the first conductive pad 110 may be different, and the curvature of the outer edge Tu of the through hole TH1 may be the same as or different from the curvature of the inner edge 110i of the first conductive pad 110.

As described above, when the outer edge Tu of the through hole TH1 and the outer edge 110u of the first conductive pad 110 are combined into a quasi-circular shape (for example, an elliptical shape), the electrical connection structure can be effectively miniaturized and occupy a relatively small space in the electronic device. In addition, the conductive material CD can still be well connected with the first conductive pad 110 and the second conductive pad 210, thereby maintaining the reliability of the electrical connection structure.

Please refer to FIG. 8, which is a cross-sectional diagram of an electronic device 20 in accordance with some embodiments of the present disclosure. It should be understood that, for clarity of explanation, some components of the electronic device 20 may be omitted in the drawings, and only some components are schematically illustrated. In accordance with some embodiments, additional features may be added to the electronic device 20 described below. In accordance with some other embodiments, some features of the electronic device 20 described below may be replaced or omitted.

As shown in FIG. 8, in accordance with some embodiments, the electronic device 20 includes an electrical connection structure 10E-1 and an electrical connection structure 10E-2. Specifically, the electrical connection structure 10E-1 is substantially the same as the electrical connection structure 10E in the embodiments shown in FIG. 2. Compared with the electronic device 10 shown in FIG. 2, the electronic device 20 further includes the electrical connection structure 10E-2. The electrical connection structure 10E-2 can be electrically connected to the electrical connection structure 10E-1. In accordance with some embodiments, in the normal direction of the first substrate 100 (for example, the Z direction in the figure), the electrical connection structure 10E-2 and the electrical connection structure 10E-1 at least partially overlap.

In detail, in accordance with some embodiments, the electrical connection structure 10E-2 may include a third substrate 300, a third conductive pad 310 and a through hole TH2. The third conductive pad 310 may be disposed between the third substrate 300 and the conductive pad 210, and the through hole TH2 may pass through the second substrate 200, and the third conductive pad 310 may be electrically connected to the second conductive pads 210 through the through hole TH2. Specifically, a conductive material is also disposed in the through hole TH2, and the third conductive pad 310 can be electrically connected to the second conductive pad 210 through the conductive material disposed in the through hole TH2.

The materials of the third substrate 300 and the third conductive pad 310 may be the same or similar to the materials of the aforementioned second substrate 200 and the second conductive pad 210, and thus will not be repeated here.

Furthermore, the electronic device 20 may include an electronic component 400 and a driving component 302. The electronic component 400 may be disposed on the first substrate 100, and the driving component 302 may be disposed on the third substrate 300. Moreover, the driving component 302 may be electrically connected to the electronic component 400 by the electrical connection structure 10E-1 and the electrical connection structure 10E-2. As mentioned above, in accordance with some embodiments, the electronic component 400 may include a light-emitting diode, but it is not limited thereto. Furthermore, in accordance with some embodiments, the driving component 302 may include an integrated circuit chip (IC), a microchip, or another suitable electronic driving component that can provide electronic signals or logic signals, but it is not limited thereto. In accordance with some embodiments, the driving component 302 may be disposed on the third substrate 300 in the form of a chip on film (COF) package or a chip on glass (COG) package, but it is not limited thereto.

The conductive material CD of the electronic device 20 can be electrically connected to the second conductive pad 210 and the third conductive pad 310 through the through holes TH1 and TH2, and then electrically connected to the driving component 302 on the third substrate 300. Through the above configuration, the driving signal of the driving component 302 can be provided to the first conductive pad 110 and multiple electronic components through the conductive path formed by the conductive material CD, the second conductive pad 210 and the third conductive pad 310. When the electronic device 20 is applied in the field of display devices, the driving signal of the driving component 302 can be transmitted from one side of the first substrate 100 to the electronic components 400 on the opposite side through the electrical connection structure 10E-1 and the electrical connection structure 10E-2. Therefore, the driving component 302 can be disposed on the back side of the first substrate 100, thereby reducing the usage rate of the peripheral area of the electronic device 20, thereby achieving technical requirements such as borderless, narrow border or seamless tiling. The electronic device 20 can therefore have good display quality.

In addition, in accordance with some other embodiments, the aforementioned electrical connection structure can also be applied to the tiled device to provide electrical connections between different parts of the tiled device. Moreover, the electrical connection structure can be used to provide conduction between any suitable amount of substrates, and the amount of electrical connection structures and substrates is not limited to those shown in the drawings of the present disclosure.

To summarize the above, in accordance with the embodiments of the present disclosure, an electronic device including an electrical connection structure is provided. The through hole and conductive pad of the electrical connection structure are configured in a specific manner, so that the conductive material can be effectively electrically connected to the conductive pad even in the miniaturized through hole. Moreover, it can reduce the contact resistance between the conductive material and the conductive pad, and has good conduction function, which can improve the reliability of the electrical connection structure and thereby improve the performance of the electronic device. The electronic device can have good electrical quality or display quality. In addition, in accordance with some embodiments of the present disclosure, the design of the electrical connection structure allows electronic components (such as driving components, etc.) to be disposed on the back side of the substrate, which can reduce the usage rate of the peripheral area of the electronic device, thereby achieving technical requirements such as borderless, narrow border or seamless tiling.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
at least one electrical connection structure, wherein the at least one electrical connection structure comprises:
a first substrate;
a first conductive pad disposed on the first substrate, wherein the first conductive pad comprises a first upper surface;
a second substrate;
a second conductive pad disposed on the second substrate, wherein the second conductive pad comprises a second upper surface;
a through hole passing through the first substrate, wherein in a top-view diagram, an area of the through hole is greater than an area of the first conductive pad; and
a conductive material partially disposed in the through hole and in contact with the first upper surface and the second upper surface.

2. The electronic device as claimed in claim 1, wherein in the top-view diagram, the first conductive pad comprises at least two continuous surfaces.

3. The electronic device as claimed in claim 1, wherein in the top-view diagram, the first conductive pad comprises one continuous surface.

4. The electronic device as claimed in claim 1, wherein in the top-view diagram, an outer edge of the through hole has at least an arc shape, and an outer edge of the first conductive pad has at least an arc shape.

5. The electronic device as claimed in claim 4, wherein in the top-view diagram, the outer edge of the through hole and the outer edge of the first conductive pad are substantially continuous.

6. The electronic device as claimed in claim 4, wherein in the top-view diagram, there is a minimum distance between an outermost edge of the through hole and an outermost edge of the first conductive pad, and the minimum distance is between 0.01 and 100 micrometers.

7. The electronic device as claimed in claim 1, wherein in the top-view diagram, an outer edge of the through hole and an outer edge of the first conductive pad are combined to form a circle or a quasi-circle.

8. The electronic device as claimed in claim 7, wherein the quasi-circle comprises an ellipse.

9. The electronic device as claimed in claim 1, wherein a contact area of the conductive material and the second conductive pad is greater than a contact area of the conductive material and the first conductive pad.

10. The electronic device as claimed in claim 1, further comprising:
an intermediate layer disposed between the first substrate and the second substrate and partially covering the second conductive pad, wherein the through hole passes through the first substrate and the intermediate layer and exposes a portion of the second upper surface.

11. The electronic device as claimed in claim 1, wherein in the top-view diagram, a ratio of the area of the through hole to the area of the first conductive pad is between 1.1:1 and 100:1.

12. The electronic device as claimed in claim 1, wherein in the top-view diagram, an outer edge of the first conductive pad has a first endpoint and a second endpoint, and the first endpoint and the second endpoint overlap with an outer edge of the through hole.

13. The electronic device as claimed in claim 1, wherein in the top-view diagram, an outer edge of the first conductive pad has a first endpoint and a second endpoint, there is a minimum distance between a center point of the first endpoint and an outermost edge of the through hole, and between a center point of the second endpoint and the outermost edge of the through hole, and the minimum distance is between 0.01 and 100 micrometers.

14. The electronic device as claimed in claim 1, further comprising another electrical connection structure, wherein the another electrical connection structure is electrically connected to the at least one electrical connection structure.

15. The electronic device as claimed in claim 14, wherein the another electrical connection structure at least partially overlaps the at least one electrical connection structure.

16. The electronic device as claimed in claim 14, wherein the another electrical connection structure comprises:
a third substrate; and
a third conductive pad disposed between the third substrate and the second conductive pad.

17. The electronic device as claimed in claim 16, wherein the another electrical connection structure further comprises:
another through hole passing through the second substrate, wherein the third conductive pad is electrically connected to the second conductive pad through the another through hole.

18. The electronic device as claimed in claim 16, further comprising:
an electronic component disposed on the first substrate; and
a driving element disposed on the third substrate,
wherein the driving element is electrically connected to the electronic component through the at least one electrical connection structure and the another electrical connection structure.

19. The electronic device as claimed in claim 1, wherein the curvature of an outer edge of the through hole is substantially the same as the curvature of an outer edge of the first conductive pad.

20. The electronic device as claimed in claim 1, wherein an inner edge of the first conductive pad comprises a single or multiple line segments, and the slopes or curvatures of the multiple line segments are partly the same and partly different.
